(19) United States
(12) Patent Application Publication
(10) Pub. No.: US 2019/0229672 A1
(43) Pub. Date: Jul. 25, 2019

(54) SYSTEMS AND METHODS FOR ACQUIRING MEASUREMENTS OF ROTOR TEMPERATURE OF ELECTRIC MACHINES

(71) Applicant: General Electric Company, Schenectady, NY (US)

(72) Inventors: Uwe Wiedmann, Clifton Park, NY (US); Xu Han, Auburndale, MA (US); Nidhishri Tapadia, Schenectady, NY (US); Jayakrishnan Unnikrishnan, Jersey City, NJ (US); Prabhakar Neti, Rexford, NY (US)

(21) Appl. No.: 15/875,761

(22) Filed: Jan. 19, 2018

(51) Int. Cl. H02P 29/60; H02P 29/66; G01R 31/34; H02P 23/14; H02P 21/16; H02P 29/64

(52) U.S. Cl. CPC H02P 29/67; H02P 29/666; G01R 31/343; H01J 35/025; H02P 21/16; H02P 29/64; H02P 23/14

(57) ABSTRACT

A system may include a motor that has a rotor and a stator. The system may include one or more sensors that measure a voltage signal of a winding of the stator. The system may include a processor that executes computer-executable instructions which, when executed, cause the processor to receive, from the one or more sensors, the voltage signal that includes an induced voltage signal associated with the winding of the stator, to determine a time constant associated with the induced voltage signal based on a decay pattern of the induced voltage signal, to determine a temperature of a rotor based on the time constant, and to adjust one or more operations of the motor based on the temperature.

### BACKGROUND

The subject matter disclosed herein relates to systems and methods for non-invasively acquiring measurements of a rotor temperature of a motor.

In non-invasive imaging systems, X-ray tubes are used in various X-ray based imaging systems, such as radiography, mammography, tomosynthesis, C-arm angiography, fluoroscopy, and computed tomography (CT) systems, as well as others. In such systems, the X-ray tubes function as a source of X-ray radiation. The X-ray radiation is emitted in response to control signals during an examination or imaging sequence. Typically, the X-ray tube includes a cathode and an anode. An emitter within the cathode may emit a stream of electrons in response to heat resulting from an applied electrical current, and/or an electric field resulting from an applied voltage. The anode may include a target that is impacted by the stream of electrons. The target may, as a result of impact by the electron beam, produce X-ray radiation to be emitted toward an imaged volume.

In such imaging systems, induction motors may drive rotation of the anode of the X-ray tubes. The induction motors may use liquid metal bearings, ball bearings, or other forms of bearings, to couple to the anode. The bearings may become less effective in high pressure and/or high temperature conditions. For example, the liquid metal bearings may become less effective in high pressure and/or high temperature conditions due to a risk of a lubricating liquid for the bearings leaking from the liquid metal bearing.

To ensure that the liquid metal bearings are operating effectively, it is now recognized that monitoring a temperature of a rotor of the induction motor may assist in operating the induction motor and extending the life of the liquid metal bearings. However, since the rotor is generally inaccessible outside the induction motor, it may be desirable to provide a simple, reliable, and cost-effective solution to monitor rotor temperature for otherwise inaccessible rotors and liquid metal bearings.

### BRIEF DESCRIPTION

Certain embodiments commensurate in scope with the originally claimed disclosure are summarized below. These embodiments are not intended to limit the scope of the claimed disclosure, but rather these embodiments are intended only to provide a brief summary of possible forms of the disclosure. Indeed, embodiments may encompass a variety of forms that may be similar to or different from the embodiments set forth below.

In one embodiment, a system may include a motor with a rotor and a stator. The system may also include one or more sensors that measure a voltage signal of a winding of the stator. The system may also include a processor that executes computer-executable instructions which, when executed, cause the processor to receive, via the one or more sensors, the voltage signal that includes an induced voltage signal associated with the winding of the stator, to determine a time constant associated with the induced voltage signal based on a decay pattern of the induced voltage signal, to determine a temperature of a rotor based on the time constant, and to adjust one or more operations of the motor based on the temperature.

In another embodiment, a control system for operating a motor may receive, via a sensor, a voltage signal associated with one or more windings of a stator in the motor. The control system may also determine a time constant associated with the induced voltage signal based on a decay pattern of the induced voltage signal. The control system may also determine a temperature of a winding of a rotor of the motor based on the time constant. The control system may also adjust one or more operations of the motor, or conditions under which the motor is operating, based on the temperature.

In yet another embodiment, a method may involve receiving, via a processor, a voltage signal from one or more sensors, where the voltage signal includes a voltage decay of an induced voltage signal associated with a first winding of a stator of a motor, where the voltage decay is associated with a time period that corresponds to when an electrical supply removes a power supply to the stator. The method may also involve determining, via the processor, a time constant associated with the voltage decay. The method may also involve determining, via the processor, a temperature of a second winding of a rotor of the motor based at least in part on the time constant. The method may also involve adjusting, via the processor, one or more operations of the motor based on the temperature.

### BRIEF DESCRIPTION OF THE DRAWINGS

These and other features, aspects, and advantages of the present disclosure will become better understood when the following detailed description is read with reference to the accompanying drawings in which like characters represent like parts throughout the drawings, wherein:

FIG. 1 illustrates a block diagram of an X-ray tube, in accordance with an embodiment;

FIG. 2 illustrates a method for non-invasively measuring a rotor temperature of a rotor in the X-ray tube of FIG. 1, in accordance with an embodiment;

FIG. 3 illustrates a graph of an example voltage signal across windings of a stator in the X-ray tube of FIG. 1, in accordance with an embodiment;

FIG. 4 illustrates a graph of a back-EMF signal from the windings of the stator in the X-ray tube of FIG. 1, in accordance with an embodiment;

FIG. 5 illustrates a graph of a filtered back-EMF signal derived from the back-EMF signal of FIG. 4, in accordance with an embodiment;

FIG. 6 illustrates a graph of a Hilbert transformed back-EMF signal magnitude derived from the filtered back-EMF signal of FIG. 5, in accordance with an embodiment; and

FIG. 7 illustrates a graph of a log transform of a back-EMF signal derived from the Hilbert transformed back-EMF signal magnitude of FIG. 6, in accordance with an embodiment.

### DETAILED DESCRIPTION

One or more specific embodiments of the present disclosure will be described below. In an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” “the,” and “said” are intended to mean that there are one or more of the elements. The terms “comprising,” “including,” and “having” are intended to be inclusive and mean that there may be additional elements other than the listed elements.

One or more specific embodiments of the present embodiments described herein will be described below. In an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Accurate monitoring of a liquid metal bearing may include monitoring a temperature of the liquid metal bearing. Monitoring the temperature of the liquid metal bearing poses a particular challenge in the application of non-invasive imaging systems because directly measuring the temperature of the liquid metal bearing is impractical in some applications. Having an inaccessible liquid metal bearing may pose less of a technical challenge if the rotor of the non-invasive imaging system is accessible for temperature measurement, as a thermal model may accurately predict the temperature of the liquid metal bearing based on the rotor temperature. However, in certain applications, measuring the temperature of the liquid metal bearing and the rotor directly may be impractical. For example, both the liquid metal bearing and the rotor may operate in a hermetically sealed vacuum enclosure and may be otherwise inaccessible for temperature measurements.

With the foregoing in mind, embodiments of the present disclosure are related to systems and methods for non-invasively measuring temperature of components within a motor. More specifically, embodiments disclosed herein may allow for performing a temperature measurement of an otherwise inaccessible part of an induction motor.

As described herein, techniques of this disclosure leverage electrical signals generated by the induction motor after an electrical supply (e.g., motor driver, stator driver) coupled to the electric machine switches off as a way to non-invasively measure the rotor temperature. To elaborate, motors with externally excited rotors with windings like induction motors with squirrel cage rotor, induction motors with wound rotor, synchronous motor with windings on the rotor or other suitable motors with windings on the rotor may induce a back-electromotive force (back-EMF) signal on the stator winding of the motor during a rotation of the rotor. As such, the back-EMF signal may be considered an induced voltage signal. The back-EMF signal is present within one or more windings of the stator and is an electrical signal (e.g., voltage). Some embodiments may leverage the back-EMF signal to determine the temperature of the rotor. For instance, during an operation of the induction motor, the electrical supply coupled to the stator may switch off at various points in time. Following the switch off of the electrical supply coupled to the induction motor, the back-EMF signal within the winding of the stator may decay, or decrease, (e.g., a voltage decay) at an exponential rate according to a time constant. The time constant of the decay of the back-EMF signal may be measured and/or correlated to the temperature of the rotor, as decay patterns of the back-EMF signal are in part based on the temperature of the rotor (e.g., different temperatures result in different time constants of the decay). Furthermore, a thermal model (e.g., a heat transfer model) may assist in calculating the effect of the temperature of the rotor on the temperature of related components (e.g., the liquid metal bearings) thermally coupled to the rotor of the induction motor.

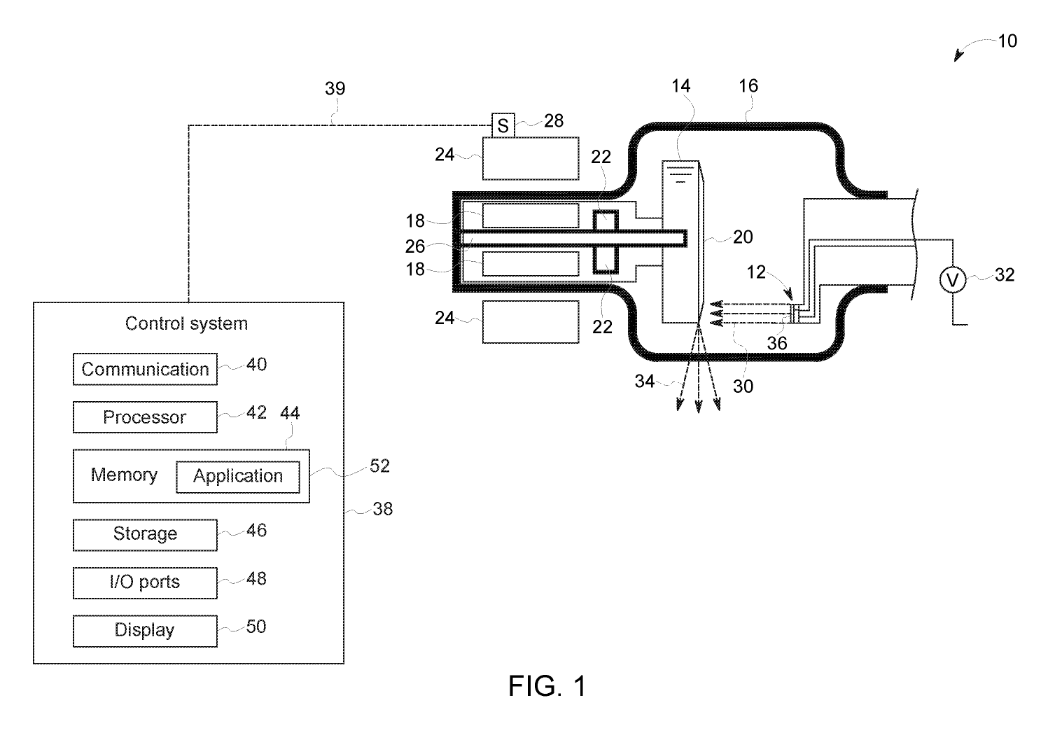

By way of introduction, FIG. 1 illustrates a block diagram of an X-ray tube 10, similar to an X-ray tube used in computed tomography (CT) machines. As illustrated, the X-ray tube 10 may include a cathode 12 and an anode assembly 14 encased in a housing 16.

The anode assembly 14 includes a rotor 18 that may turn an anode 20 (e.g., a rotating anode disc). As illustrated the rotor 18 couples to the anode 20 through a bearing 22 that may be lubricated with liquid metal. A stator 24 may electrically excite the rotor 18 causing the anode 20 and the rotor 18 to rotate. The anode 20 and the rotor 18 may rotate about a stationary shaft 26. If the electrical supply coupled to the stator 24 switches off and/or decreases, a rotor rotational speed may decrease until the rotor 18 reaches a steady state rotor rotational speed. The rotor 18 may induce a voltage (e.g., an induced voltage) across a winding of the stator 24, known as the back-EMF. Sensors 28 may measure the back-EMF signal after the electrical switch off of an electrical supply to stator 24 using a voltage sensor. It is noted that the sensors 28 may include additional sensors to measure the back-EMF signal and/or to make additional measurements, as described herein. It is additionally noted that an optional additional winding separate from the discussed winding of the stator 24 (e.g., a main stator winding) may be used to measure the back-EMF signal, where the optional additional winding may be designed specifically for the purpose of measuring the back-EMF.

During operation of the X-ray tube 10, the anode 20 emits an X-ray beam 34 when struck by an electron beam 30 emitted from the cathode 12. In some X-ray tubes, electrostatic potential differences in excess of 20 kV are created between a cathode assembly 36 coupled to voltage source 32 and the anode 20. As such, electrons may be emitted by the cathode assembly 36 that accelerate towards the anode 20. As a result, during operation of the X-ray tube 10, heat may generate around the anode 20.

The X-ray tube 10 is supported by the anode assembly 14 and the cathode assembly 36, with the housing 16 defining an area of relatively low pressure (e.g., a hermetically sealed vacuum enclosure). For example, the housing 16 may include glass, ceramics, stainless steel, or other suitable materials. The anode 20 may be manufactured of any metal or composite, such as tungsten, molybdenum, copper, or any material that contributes to Bremsstrahlung radiation (e.g., deceleration radiation) when bombarded with electrons. The surface material of the anode 20 is typically selected to have a relatively high thermal diffusivity to withstand the heat generated by electrons impacting the anode 20. The space between the cathode assembly 36 and the anode 20 may be evacuated to minimize electron collisions with other atoms and to increase high voltage stability. Moreover, such evacuation may advantageously cause a magnetic flux to interact with (e.g., steer, focus) the electron beam 30.

During operation, an electrical supply coupled to the stator 24 may operate to switch off at various points in time. The sensors 28 may measure the back-EMF signal from the windings of the stator 24 that corresponds to a time interval that includes when the electrical supply switches off. The data acquired by the sensors 28 may be transmitted to a control system 38. Additionally or alternatively, the sensors 28 may measure additional electrical properties of the stator 24, such as voltage, current, power, power factor, and the like. To make a measurement, the control system 38 may transmit a control signal to the sensors 28 to initiate the measurement. Additionally or alternatively, the sensors 28 may be programmed to make the measurement automatically. When the measurement is complete, the sensors 28 may transmit to the control system 38 via a communication path 39 the measurement and/or a signal indicative of the measurement. The communication path 39 may be any suitable wireless or wired communication transmission line that enables the transfer of data from the sensors 28 to the control system 38.

Additionally, in the illustrated embodiment, the control system 38 may include a communication component 40, a processor 42, a memory 44, a storage 46, input/output (I/O) ports 48, a display 50, and the like. The communication component 40 may be a wireless or wired communication line that may facilitate communication with various other processors, and the like. The processor 42 may be any type of computer processor or microprocessor capable of executing computer-executable code (e.g., computer-executable instructions). The memory 44 and the storage 46 may be any suitable articles of manufacture that can serve as media to store processor-executable code, data, or the like. These articles of manufacture may represent computer-readable media (e.g., any suitable form of memory or storage) that may store the processor-executable code used by the processor 42 to perform the presently disclosed techniques.

The memory 44 or the storage 46 may be used to store data downloaded via the communication component 40. The memory 44 and the storage 46 may be used to store data received via the I/O ports 48, data analyzed by the processor 42, or the like. The memory 44 and the storage 46 may be used to store data providing details regarding operational parameters for the X-ray tube 10, where if the data received via the I/O ports 48 and/or data analyzed by the processor 42 does not satisfy (e.g., exceeds) an operational parameter, the control system 38 may respond by adjusting an operation of the X-ray tube 10, the stator 24, the rotor 18, or a system that the X-ray tube 10 is associated with.

The memory 44 or the storage 46 may also be used to store an application 52, a firmware, software, or the like. The application 52, when executed by the processor 42, may also enable the control system 38 to perform preliminary analyses based on the data downloaded. The preliminary analyses may include determining whether the data downloaded are within an expected range of values. Examples of data may include motor back-EMF signals and the like. The application 52, when executed by the processor 42, may also enable the control system 38 to provide an alert or indication when the downloaded data is outside an expected range of values. It should be noted that the alert or indication may be provided in any suitable manner (e.g., visual or audio alerts). In some embodiments, the alert may cause the application 52 to alter the appearance of the display 50, the control system 38, or the like, such that the control system 38 is aware of the alert even when the control system 38 is in a sleep or power-savings mode. That is, the control system 38 may receive the alert, which may cause the control system 38 to exit a current mode of operation (e.g., sleep) to provide an indication to the user of the alert.

The I/O ports 48 may be interfaces between the control system 38 and other types of equipment, computing devices, or peripheral devices. The display 50 may include any type of electronic display such as a liquid crystal display, a light-emitting-diode display, and any type of audio transducer such as a speaker. In certain embodiments, the display 50 may be a touch screen display or any other type of display capable of receiving inputs from the user of the control system 38. In certain embodiments, results of the preliminary analyses and/or the alert or indication (e.g., provided when the downloaded data is outside an expected range of values) may be presented using the display 50.

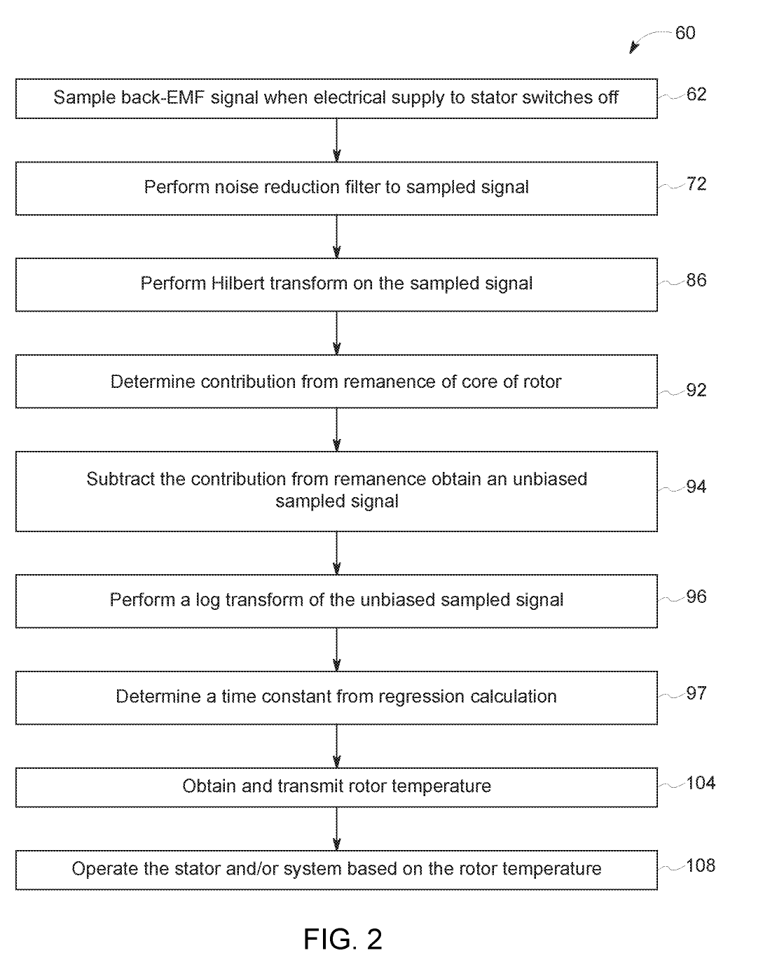

Referring again to the X-ray tube 10, during operation of the X-ray tube 10, heat may generate due to the electron beam 30 striking the anode 20. The anode 20 may then convert a portion of the overall energy of the electron beam 30 into the X-ray beam 34. The remaining energy is locally converted into heat and may conduct (e.g., thermal conduction) to the liquid metal of the bearing 22 causing a change in performance. The housing 16 may encapsulate the rotor 18, thereby encapsulating the bearing 22, and making direct access to the bearing 22 and the rotor 18 challenging. Thus, a technique for non-invasively estimating and monitoring the rotor temperature is described in FIG. 2.

With the foregoing in mind, FIG. 2 illustrates a flow diagram of a method 60 for non-invasively measuring the rotor temperature through using a time constant associated with a decay of the induced back-EMF signal present after the electrical supply coupled to the stator 24 is disconnected (e.g., switched off). Although the method 60 is described below as being performed by the control system 38, it should be noted that the method 60 may be performed by any suitable processor to estimate and monitor any suitable temperature of any suitable rotor. Moreover, although the following description of the method 60 is described in a particular order, it should be noted that the method 60 may be performed in any suitable order.

Referring to FIG. 2, at block 62, the control system 38 may sample the back-EMF signal when an electrical supply to the stator 24 switches off. To elaborate, the control system 38 may sample the back-EMF signal through measurement via the sensors 28 when an electrical supply coupled to the stator 24 switches off. The electrical supply coupled to the stator 24 may switch off during a normal operation of the stator 24 (e.g., to mitigate heat generation during operation, to measure the rotor temperature). When the electrical supply coupled to the stator 24 switches off, the voltage measured across the windings of the stator 24 by the sensors 28 corresponds to the back-EMF signal generated by a first contribution from a magnetic field of the rotor 18 generated by currents flowing through the rotor 18 and a second contribution from a remanence in a core of the rotor 18. In some embodiments, the control system 38 may discard a first portion of the back-EMF signal that may include errors (e.g., changes to the back-EMF signal resulting from the switching off of the electrical supply, switching transients) and/or may not be indicative of an exponential decay portion of the back-EMF signal. As such, the control system 38 may retain a second portion of the back-EMF signal that includes the exponential decay of the back-EMF signal that may be relevant for interpolating a time constant associated with the exponential decay.

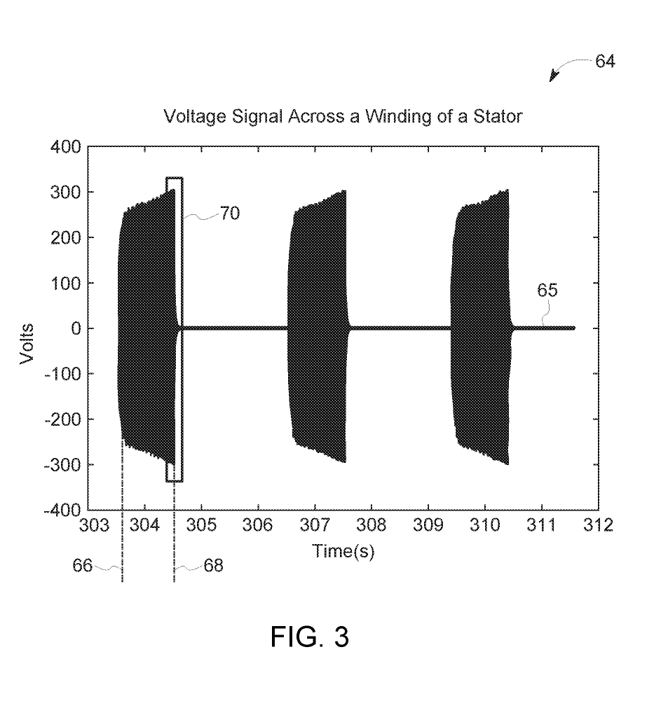

To continue description of the back-EMF signal, FIG. 3 illustrates a graph 64 of a voltage signal 65 measured across one or more windings of the stator 24 and includes the voltage signal 65 at a time 66 and at a time 68. The voltage signal 65 at the time 66 is the voltage signal 65 resulting from the electrical supply coupled to the stator 24 switching on, while the voltage signal 65 at the time 68 is the voltage signal 65 resulting from the electrical supply coupled to the stator 24 switching off. Thus, the graph 64 illustrates three switch-on and switch-off cycles of the electrical supply coupled to the stator 24. The graph 64 shows that at the time 66, when the electrical supply coupled to the stator 24 switches on, the voltage signal 65 increases to around several hundred volts from around zero volts until the time 68. At the time 68, when the electrical supply coupled to the stator 24 switches off, the voltage signal 65 exponentially decays to approximately zero volts and remains approximately zero volts until the electrical supply switches on again. The voltage signal 65 from the time 66 to the time 68 includes the back-EMF signal and voltages (e.g., resistive voltages, inductive voltages) present in the motor.

After the time 68 and during the exponential decay of the voltage signal 65, the control system 38 may measure the back-EMF signal, as described in the block 62. This isolation of the back-EMF signal is possible because the electrical supply switched off at time 68 making a current from the electrical supply equal zero. The sampling and/or measurement of the back-EMF signal may occur during a measurement window 70. The measurement window 70 may include the first portion of the back-EMF signal that is to be removed, as discussed above, and the second portion of the back-EMF signal that is to be analyzed.

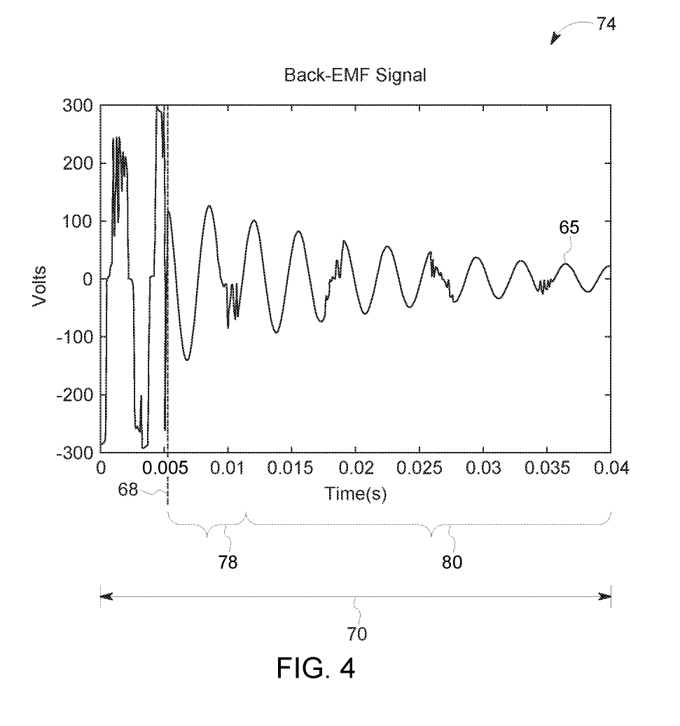

FIG. 4 illustrates a graph 74 of the voltage signal 65 and further describes the first portion of the back-EMF signal and the second portion of the back-EMF signal. The graph 74 includes the time 68 and the measurement window 70 including a first portion 78 of the back-EMF signal, and a second portion 80 of the back-EMF signal. The first portion 78 of the back-EMF signal may include noise from the switching off of the electrical supply coupled to the stator 24 (e.g., switching transients). In some embodiments, the control system 38 may discard the first portion 78 of the back-EMF signal and retain the second portion 80 of the back-EMF signal for use in determining the rotor temperature. It is noted that during the decay of the voltage signal 65 after the time 68 and until the electrical supply is switched on again, the voltage signal 65 represents the back-EMF signal because a negligible amount of additional voltages affects the voltage signal 65. As such, the voltage signal 65 after time 68 may represent the back-EMF signal.

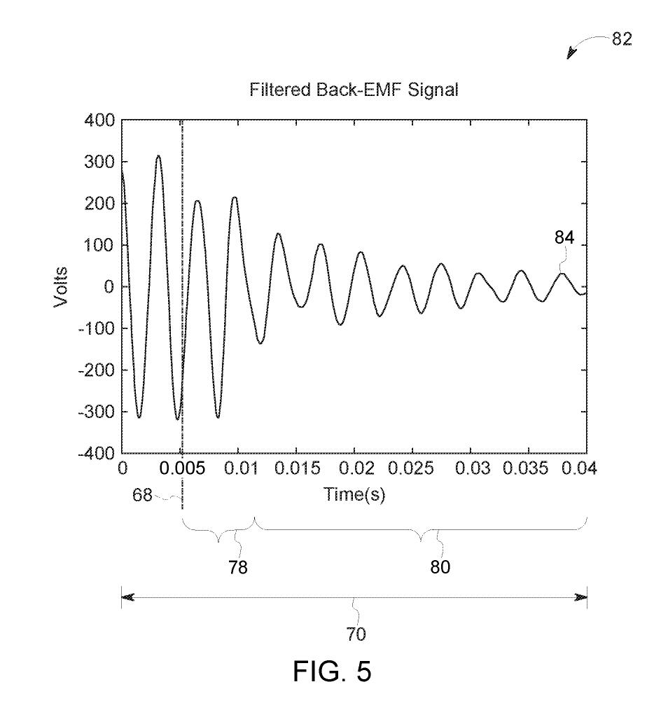

Returning to FIG. 2, at block 72, the control system 38 may perform a noise reduction filter to the sampled signal that is the back-EMF signal. Filtering the sampled signal creates a filtered back-EMF signal. The filtering may be part of a signal-adjustment routine performed by the control system 38. The control system 38 may filter the back-EMF signal to reduce levels of noise introduced into the back-EMF signal. To perform the filtering, the control system 38 may transmit the sampled back-EMF signal through filtering software (e.g., code performing the effects of the filter) or hardware (e.g., filter circuit). To elaborate further, FIG. 5 illustrates a filtered back-EMF signal 84.

FIG. 5 illustrates a graph 82 of the filtered back-EMF signal 84 that includes the time 68, the measurement window 70, the first portion 78 of the back-EMF signal, and the second portion 80 of the back-EMF signal. The graph 82 illustrates the voltage signal 65 after filtering to create the filtered back-EMF signal 84. As illustrated, the filtered back-EMF signal 84 includes a reduced amount signal noise, as shown in the reduction of signal variance as compared to the graph 74 of FIG. 4. In this way, the control system 38 may filter the back-EMF signal to create the filtered back-EMF signal 84 to reduce the amount of noise in the signal introduced into the measurement of the rotor temperature.

Returning again to FIG. 2, at block 86, the control system 38 may perform a Hilbert transform on the filtered back-EMF signal 84, derived from the sampled signal, to extract an improved representation of the exponential decay of the filtered back-EMF signal 84. The Hilbert transform may be part of a signal-adjustment routine performed by the control system 38. Improving the representation of the exponential decay of the filtered back-EMF signal 84 may improve the ability of the control system 38 to determine a time constant from the exponential decay because the time constant may become more apparent in the filtered back-EMF signal 84. The time constant determined from the exponential decay is used to determine the rotor temperature because the time constant of the decay relates to the resistance of the rotor, as described herein. To improve the representation of the exponential decay of the filtered back-EMF signal 84, and thus improve an accuracy of calculation of the time constant, the control system 38 may correct for the contribution from the remanence on the back-EMF signal through taking the Hilbert transform of the filtered back-EMF signal 84.

To elaborate further on the remanence, an overall value of the back-EMF signal may include contribution from a magnetic field produced by residual currents in windings of the rotor 18 after the electrical supply coupled to the stator 24 is switched off, and from a magnetic field produced by residual magnetism, or the remanence, in the core of the rotor 18. The contribution to the back-EMF signal from the magnetic fields produced by the residual currents in the windings and the magnetic fields produced by the remanence in the core is illustrated with Equation 1, where E(t) represents the back-EMF signal value changing with time, A_{I} represents a contribution from magnetic field produced by a residual current in a winding of a rotor, A_{R} represents a contribution from magnetic fields produced due to remanence from a core of the rotor, t represents time, ϕ represents a phase shift, λᵣ represents an exponential rate of decay and is a negative reciprocal of a time constant, and ωᵣ represents the rotational speed of a rotor.

As shown in Equation 1 with a first term, A_{I}e^{-λ}^{ᵣ}^{t}, the induced voltages in windings of the stator 18 may decay exponentially at a rate based on the time constant, since e^{-λ}^{ᵣ}^{t} drives the decay of the contribution from A_{I}. The control system 38 assumes a constant rotational speed of the rotor 18 during the measurement window 70 to simplify calculation.

E(t)=(A_{I}e^{-λ}^{ᵣ}^{t}+A_{R})cos(ωᵣt+ϕ) [1]

Thus, to measure time constant τᵣ, the exponential rate of decay λᵣ may be solved for in the first term A_{I}e^{-λ}^{ᵣ}^{t}. To do this, the Hilbert transform is applied to create a Hilbert transformed back-EMF signal from the filtered back-EMF signal 84.

The Hilbert transform may calculate an analytic signal (e.g., E_{A}(t)) that includes a real part and an imaginary part for representing the filtered back-EMF signal 84, where the real part is the filtered back-EMF signal 84 and the imaginary part is the imaginary value of the Hilbert transformed filtered back-EMF signal. The control system 38 may retain the magnitude of the Hilbert transformed back-EMF signal, |E_{A}(t)| of Equation 2, to improve the representation of the exponential decay of the filtered back-EMF signal 84 (e.g., by effectively eliminating the effect of the cos(ωᵣt+ϕ) term in calculations). Equation 2 defines a Hilbert transformed back-EMF signal magnitude, as is used in descriptions herein.

|E_{A}(t)|=A_{I}e^{-λ}^{ᵣ}^{t}+A_{R} [2]

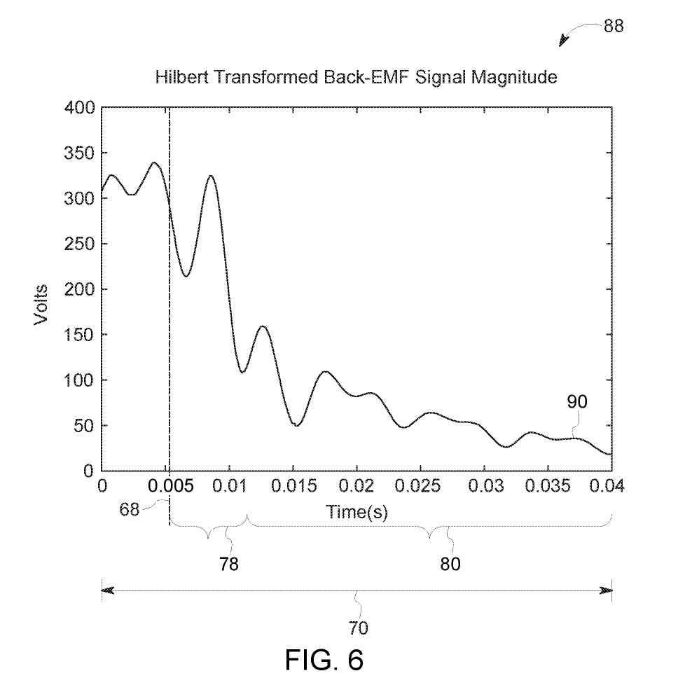

FIG. 6 illustrates a graph 88 of a Hilbert transformed back-EMF signal magnitude 90. The Hilbert transformed back-EMF signal magnitude 90 includes contributions from the remanence, A_{R}, and from the residual currents in the windings of the rotor 18, A_{I}e^{-λ}^{ᵣ}^{t}, as described herein. From the Hilbert transform and the described signal processing, the Hilbert transformed back-EMF signal magnitude 90 may improve the representation of the exponential decay in the second portion 80 of the back-EMF signal.

Returning to FIG. 2, at block 92, the control system 38 may determine a contribution from the remanence of the core of the rotor 18. The contribution from the remanence may be determined from the Hilbert transformed back-EMF signal magnitude 90. The determining the contribution may be included in a signal-adjustment routine performed by the control system 38. To determine the contribution from the remanence, the control system 38 may wait for a desired time interval (e.g., a time interval equal to 20 times an expected value for the time constant) to pass after electrical supply switches off before measuring for the contribution from the remanence. The contribution from the remanence may remain at a constant amplitude. Thus, the control system 38 may wait to measure the contribution from the remanence until the contribution from the residual currents in the windings of the rotor 18 is negligible. As such, the control system 38 may wait the desired time interval before measuring for the contribution to the back-EMF signal from remanence so that when the voltage signal 65 at the desired time interval is measured, the value of the voltage signal 65 represents the contribution from the remanence.

In some embodiments, the rotor rotational speed may decrease while the control system 38 waits for the desired time interval. In these embodiments, the control system 38 may use three measurements to determine the contribution from the remanence of the core of the rotor 18 to the back-EMF signal: a first measurement for the value of the voltage signal 65 at the desired time interval, a second measurement for the rotor rotational speed at the desired time interval, and a third measurement for the rotor rotational speed at the switch off of the electrical supply coupled to the stator 24 (e.g., the time 68). Using these three measurements, the control system 38 may change the contribution to the back-EMF signal from the remanence based on the ratio of the third measurement to the second measurement.

At block 94, the control system 38 may subtract the contribution from the remanence to create an unbiased sampled signal. The control system may create an unbiased Hilbert transformed back-EMF signal magnitude from the Hilbert transformed back-EMF signal magnitude 90, derived from the sampled signal and therefore creating an unbiased sampled signal. Subtracting the contribution from the remanence to create the unbiased Hilbert transformed back-EMF signal improves accuracy of calculating the time constant and of calculating the rotor temperature. The subtraction may be a part of a signal-adjustment routine performed by the control system 38.

At block 96, the control system 38 may perform a log transform of the unbiased sampled signal, where the unbiased sampled signal may be the unbiased Hilbert transformed back-EMF signal magnitude based on the sampled signal. The log transform may be a part of a signal-adjustment routine performed by the control system 38. The control system 38 performing the log transform of the unbiased Hilbert transformed back-EMF signal magnitude may follow Equation 3, where Equation 3 shows the log transform of unbiased Hilbert transformed back-EMF signal magnitude represented by a difference between the contribution from the remanence (A_{R}) and the Hilbert transformed back-EMF signal magnitude 90 (|E_{A}(t)|). The result of the log transform is represented by E_{log}(t) and will be referred to as a log transform of the back-EMF signal.

E_{log}(t)=log(|E_{A}(t)|−A_{R}) [3]

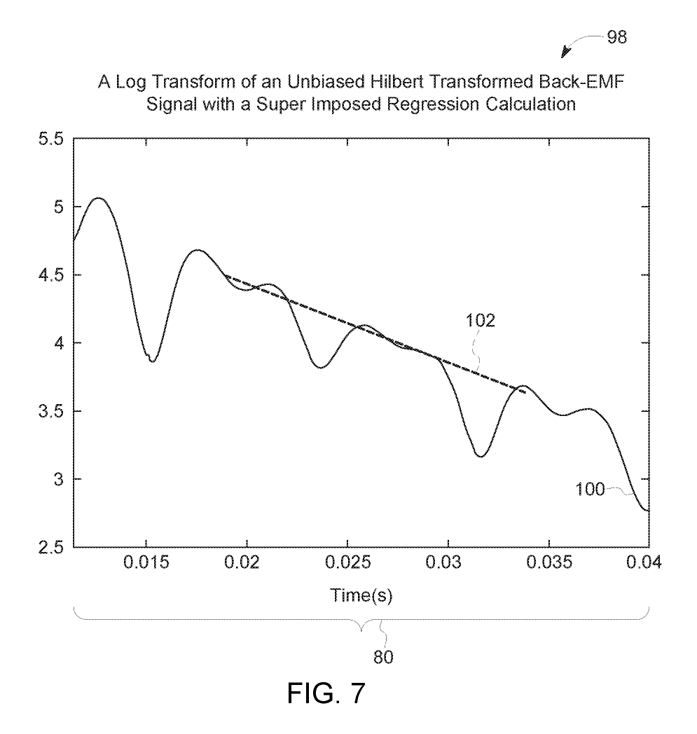

At block 97, the control system 38 may determine the time constant from regression calculation. The control system 38 may perform a regression calculation (e.g., linear regression) of the log transform of the back-EMF signal (e.g., the log transform of the unbiased sampled signal). The regression calculation creates a slope representative of an upper signal envelope associated with the log transform of the back-EMF signal. The control system 38 may thus use the slope to find the time constant. The control system 38 may then calculate the time constant by taking the negative reciprocal of the slope obtained from the regression calculation. FIG. 7 illustrates the principle of the log transform and the regression calculation from the block 96 and the block 97.

FIG. 7 illustrates a graph 98 of a log transform of the back-EMF signal 100, where the log transform of the back-EMF signal 100 is derived from the Hilbert transformed back-EMF signal magnitude, as described herein. The graph 98 illustrates a slope 102, where the slope 102 is determined from the control system 38 performing the regression calculation of the log transform of the back-EMF signal 100, as described herein. The slope 102 represents the negative reciprocal of the time constant and is generally indicative of decreasing slope associated with an upper signal envelope of the log transform of the back-EMF signal 100. Thus, to calculate the time constant, the control system 38 may invert and negate the value found as the slope 102. It is noted, that the control system 38 may obtain a numerical slope as the result of the regression calculation. As illustrated, the slope 102 is a superimposed representation of the numerical slope calculation to show a relationship between the log transform of the back-EMF signal 100 and the slope 102 of the upper signal envelope.

Returning to FIG. 2, at block 104, the control system 38 may obtain and transmit the rotor temperature. Generally, the time constant may be used to calculate rotor temperature since the time constant changes independent of certain mechanical parameters (e.g., speed, torque) and, as illustrated in Equation 4, the time constant (τᵣ) may depend on the ratio between rotor inductance (Lᵣ) and rotor resistance (Rᵣ), where the rotor resistance depends on the rotor winding temperature. Estimation of the rotor temperature may presume that the rotor inductance does not change throughout the measurement window 70, causing the rotor temperature to be based on the rotor resistance and the time constant. The rotor resistance changes based on the change in temperature and on the temperature coefficient of resistivity (α) of the material of a path for currents in the rotor. Equation 5 expresses the rotor resistance at the final temperature (Rₜ) as a function of the temperature coefficient of resistivity, the initial temperature (Tₒ), the final temperature (Tₜ), and the resistance at initial temperature (Rₒ).

$$\begin{matrix}{τ}_{r} = \frac{{L}_{m} + {L}_{lr}}{{R}_{r}} = \frac{{L}_{r}}{{R}_{r}} & [ 4 ] \\ {R}_{t} = {R}_{o} ( 1 + α ( {T}_{t} - {T}_{o} ) ) & [ 5 ]\end{matrix}$$

Thus, the temperature coefficient of resistivity of the material, the resistance at a known initial temperature, and the resistance at a final temperature may provide enough information to determine the final rotor temperature. The time constant may facilitate in determining the rotor resistance and hence, determining the temperature of rotor winding may use the time constant as a replacement for the rotor resistance. Finding the temperature of the rotor winding may provide sufficient information for monitoring the rotor temperature and thus may non-invasively measure rotor temperature for the purposes of monitoring and controlling a stator and/or a motor based on the rotor temperature.

Equation 6 and Equation 7 help to describe this theory. Equation 6 defines an initial time constant at an initial temperature (τᵣₒ) as a ratio of rotor inductance at the initial temperature (Lᵣₒ) to rotor resistance at the initial temperature (Rᵣₒ). The initial time constant at an initial temperature may represent the electrical time constant of the current decay in a rotor for an initial temperature. Equation 7 highlights a final time constant at a final temperature (τᵣₜ) as a ratio value of rotor inductance at the final temperature (Lᵣₜ) to rotor resistance at the final temperature (Rᵣₜ). Substituting Equation 5 for the rotor resistance value at the final temperature (Tₜ), in addition to substituting the value for the rotor inductance at the initial temperature (Tₒ), may lead to an interim representation of Equation 7. Thus, the initial time constant may substitute the rotor inductance at the initial temperature divided by the rotor resistance at the initial temperature

$$( e . g . , \frac{{L}_{ro}}{{R}_{ro}} )$$

leading to the final representation of Equation 7.

$$\begin{matrix}{τ}_{ro} = \frac{{L}_{ro}}{{R}_{ro}} & [ 6 ] \\ {τ}_{rt} = \frac{{L}_{rt}}{{R}_{rt}} = \frac{{L}_{ro}}{{R}_{ro} ( 1 + α ( {T}_{t} - {T}_{o} ) )} = \frac{{τ}_{ro}}{( 1 + α ( {T}_{t} - {T}_{o} ) )} & [ 7 ]\end{matrix}$$

As generally shown through Equation 7, the time constant for a particular inductance and resistance value at a particular rotor temperature may facilitate in determining the rotor temperature at a different time constant value, if the particular inductance is known. Thus, the control system 38 may use the initial time constant and final time constants to determine the final rotor temperature.

Assuming the final rotor inductance equals the initial rotor inductance, and the final rotor resistance changes based on the change in temperature (Tₜ−Tₒ) and based on the temperature coefficient of resistivity (α), the Equation 7 may be used to determine the rotor temperature based on the time constant, as shown with Equation 8.

At the block 104, the control system 38 may determine the rotor temperature based on Equation 8. The control system 38 may use an initial time constant, an initial rotor temperature, and a temperature coefficient of resistivity saved in memory 44, received by I/O ports 48, or otherwise obtained, and the time constant found with the regression calculation at the block 97 to determine the final rotor temperature. It is noted that the control system 38 may have the initial time constant and the initial rotor temperature preprogrammed into the memory 44 prior to beginning the method 60, for example, during a calibration, or a setup, of the control system 38. It is also noted that inductance values for the initial time constant and the final time constant may be saved in memory 44, received by I/O ports 48, or otherwise obtained. In some embodiments, the initial time constant and initial rotor temperature represent values obtained at a time where the rotor temperature is assumed the same as an ambient temperature of an environment the rotor 18 is used in (e.g., after a time period of inactivity such that no heat was generated). It is noted that in these embodiments, if the ambient temperature of the environment changes, the control system 38 may be re-calibrated to represent a new initial time constant and new initial rotor temperature.

$${T}_{t} = {T}_{o} + \frac{1}{α} ( \frac{{τ}_{r 0}}{{τ}_{rt}} - 1 ) \qquad [ 8 ]$$

After obtaining the final rotor temperature, the control system 38 may transmit a signal indicative of the final rotor temperature to the display 50 to show the final rotor temperature (e.g., a visualization of the transmitted temperature to be depicted on a display), to memory 44 to store, and/or to the communication component 40 to transmit, and the like. Additionally or alternatively, at block 108, the control system 38 may transmit control signals to the electrical supply coupled to the stator 24 based on the signal indicative of the final rotor temperature and/or based on the final rotor temperature, as a way to operate the stator 24 to change an operation of the X-ray tube 10. In addition to changing the operation of the X-ray tube 10, in embodiments where additional X-ray tubes 10 are configured to operate in a system, the control system 38 may transmit one or more control signals to one or more control systems 38 of the additional X-ray tubes 10 and/or to respective electrical supplies of the additional X-ray tubes 10 coupled to respective stators 24, where the one or more control signals may be based on the signal indicative of the final rotor temperature and/or based on the final rotor temperature. In other words, the control system 38 may transmit control signals to change an operation of a single X-ray tube 10 or multiple X-ray tubes 10 through changing an operation of one or more motors associated with one or more X-ray tubes 10, or through changing the conditions under which one or more X-ray tubes 10 are operating, for example via an adjustment to an operation of one or more motors or heat exchangers, based on the rotor temperature.

By way of example, the control system 38 may operate as part of a control loop. The control system 38 may automatically perform an adjustment to the electrical supply coupled to the stator 24 based on the final rotor temperature. The control system 38 performing the adjustment to the electrical supply may control one or more operations of the motor. In this way, the adjustment to an operation of the motor or the system may cause a change of conditions under which the motor is operating. For example, the adjustment to the operation of the motor may cause a change in ambient temperature around, or near, the motor. Similarly, the control system 38 may adjust a system coupled to the motor to cause a change in the conditions under which the motor is operating (e.g., temperature, gravitational-force, pressure).

Additionally or alternatively, a user may operate the control system 38 to perform one or more adjustments based on the final rotor temperature. The control system 38 may perform one or more adjustments based on the final rotor temperature to the electrical supply coupled to the stator 24. In either case, the control system 38 may compare the final rotor temperature to one or more thresholds to determine if the final rotor temperature is within the threshold. For example, the control system 38 may increase a rotation speed of the rotor 18 (e.g., increasing rotation speeds of the anode 20) in response to an increase in rotor temperature. Additionally or alternatively, through the threshold comparison, the control system 38 may alter the operating frequency or operation of the X-ray tube 10 in response to the rotor temperature being outside a threshold. The reduction of operating frequency or change in operation of the X-ray tube 10 may occur at a system-wide level, and as such may affect the X-ray tube 10 or multiple additional X-ray tubes 10 of the system of X-ray tubes 10. As a result, the control system 38 may prevent certain components (e.g., bearing) of the system or the system as a whole from wearing down or operating under non-ideal circumstances.

In performing the method 60, the control system 38 may assume the rotational speed, ωᵣ, to stay constant over the measurement window 70, as described herein. The measurement window 70 may be based on a mechanical time constant of rotating components of the system such that a change in rotational speed is minimal, or kept to a minimum. It is noted that potential inaccuracies in the time constant calculation from making the assumption may be overshadowed by the noise in the sampling of the back-EMF signal, making the effect of the assumption negligible. In this way, the control system 38 may assume the rotor rotational speed to stay constant over the measurement window 70 in the implementations where the inaccuracies of the assumption fall below the level of expected noise of the measurements.

In implementations of the method 60 where it is desired for the control system 38 to account for a change in the rotor rotational speed over the measurement window 70 (e.g., when the inaccuracy of the assumption exceeds the level of expected noise), the control system 38 may account for the effect of the change in the rotor rotational speed on the back-EMF signal by modeling an amplitude term (A_{I}e^{-λ}^{ᵣ}^{t}+A_{R}) as being proportional to the instantaneous rotor rotational speed (ωᵣ(t)) with a constant of proportionality (c), and by modeling an instantaneous phase as an integral of the instantaneous frequency. In some embodiments, the control system 38 may ignore the effect of the rotor rotational speed on the instantaneous phase term and may account for an effect of the rotor rotational speed (ωᵣ(t)) on the amplitude, as described with Equation 9.

E(t)≈c(A_{I}e^{-λ}^{ᵣ}^{t}+A_{R})ωᵣ(t)cos(ωᵣ(0)+ϕ) [9]

The control system 38 may follow the method 60 to determine the Hilbert transformed back-EMF signal, from the block 72 to the block 94. Then, the control system 38 may compensate for the rotor rotational speed variation after determining a rotor rotational speed at a final time of the measurement window 70. A variety of approaches for estimating the instantaneous speed of the rotor may be implemented by the control system 38 (e.g., tracking the dominant frequency in time using a spectrogram, or counting the number of zero-crossings per unit time). The control system 38 may compensate for the rotor rotational speed variation, using Equation 9, prior to computing the time constant at the block 96.

Different embodiments of the control system 38 may employ several variations of the method 60. In one embodiment, the control system 38 may use a rotor temperature in a thermal model stored in memory 44, stored in the application 52, or otherwise accessible by the processor 42 to estimate other temperatures of interest, such as the temperature of the bearing 22.

In another embodiment, the control system 38 may perform additional motor control operations based on the rotor temperature. In the additional motor control operations, the control system 38 may perform measurements of the initial rotor temperature and the initial time constant. In these embodiments, the control system 38 may store indications of these calculations for future use in the calculations associated with method 60. Furthermore, additional control systems, similar to the control system 38, may exist to perform the additional motor control operations. The additional control systems may communicate relevant calculations to the control system 38 coupled to the stator 24 for future and/or concurrent use. It is noted that in some embodiments, the control system 38 and/or the additional control systems may perform system control operations, where in response to the rotor temperature, the conditions under which one or more X-ray tubes 10 are operating are adjusted, for example via an adjustment to an operation of one or more motors or heat exchangers.

In another embodiment, the control system 38, at the block 62, may use longer intervals of sampling the back-EMF signal if a signal-to-noise ratio is low for the application. The control system 38 may determine specific sampling intervals through indication received through I/O ports 48, from memory 44, and/or from performing control functions to determine what the desired sampling interval is based on the signal-to-noise ratio.

In another embodiment, the control system 38 may account for the change in rotor inductance from a time of an initial calibration to a time of the back-EMF signal sampling. For example, the control system 38 may account for the change in rotor inductance by implementing a look-up table, where the control system 38 may look-up the rotor inductance based on relevant measurements (e.g., electrical frequency, voltage, current, speed) for use in calculations.

Technical effects of the present disclosure include systems and methods for the non-invasive measurement of the rotor temperature of an induction motor. Measuring the rotor temperature using the non-invasive method may make possible the temperature estimation of otherwise inaccessible elements coupled or near to the rotor, like the bearings of an X-ray tube. As described, a control system may use a thermal model with the rotor temperature to estimate the temperature of the bearings of the X-ray tube and/or additional or alternative inaccessible elements coupled to the rotor. It is understood that while described in terms of non-invasive imaging systems, the non-invasive method of rotor temperature measurement may be used in a variety of electrical machines that have an arrangement for the rotor currents to flow after the stator is disconnected from the stator electrical supply such as squirrel cage induction motors and/or synchronous machines with damper bars.

This written description uses examples to disclose the disclosure, including the best mode, and also to enable any person skilled in the art to practice the disclosure, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A system, comprising:
a motor comprising a rotor and a stator;
one or more sensors configured to measure a voltage signal of a winding of the stator; and
a processor configured to execute computer-executable instructions which, when executed, cause the processor to:
receive, via the one or more sensors, the voltage signal, wherein the voltage signal comprises an induced voltage signal associated with the winding of the stator;
determine a time constant associated with the induced voltage signal based on a decay pattern of the induced voltage signal;
determine a temperature of a rotor based at least in part on the time constant; and
adjust one or more operations of the motor based on the temperature.

2. The system of claim 1, wherein the processor is configured to adjust the one or more operations of the motor by adjusting one or more properties of an electrical supply configured to couple to the stator.

3. The system of claim 1, wherein the processor is configured to determine an additional temperature of a component thermally coupled to the rotor based on the temperature and a thermal model.

4. The system of claim 1, wherein the processor is configured to determine the temperature according to:
$${T}_{t} = {T}_{o} + \frac{1}{α} ( \frac{{τ}_{ro}}{{τ}_{rt}} - 1 )$$
wherein Tₜ is the temperature, Tₒ is an additional temperature of the rotor, α is a temperature coefficient of resistivity of a winding of the rotor, Tᵣₒ is an additional time constant at the additional temperature of the rotor, and Tᵣₜ is the time constant.

5. The system of claim 1, wherein the processor is configured to determine the time constant based on a regression calculation configured to determine a slope of the decay pattern of the induced voltage signal, wherein the decay pattern is associated with a switching off of an electrical supply configured to couple to the stator, and wherein the slope relates to the time constant.

6. The system of claim 5, wherein the electrical supply is configured to switch off a plurality of times during an operation of the motor.

7. The system of claim 1, wherein the processor is configured to determine the time constant of the induced voltage signal comprises performing a signal-adjustment routine on the induced voltage signal.

8. The system of claim 7, wherein the signal-adjustment routine comprises:
applying a noise reduction filter to the induced voltage signal;
applying a Hilbert transform to the induced voltage signal;
correcting a contribution from remanence of a core of the rotor to the induced voltage signal;
performing a log transform on the induced voltage signal; or
any combination thereof.

9. A system, comprising:
a controller configured to:
receive, via a sensor, a voltage signal associated with one or more windings of a stator in the motor;
determine a time constant associated with the induced voltage signal based on a decay pattern of the induced voltage signal;
determine a temperature of a winding of a rotor of the motor based at least in part on the time constant; and
adjust one or more operations of the motor, or conditions under which the motor is operating, based on the temperature.

10. The system of claim 9, wherein the rotor is configured as:
a squirrel cage rotor;
a rotor comprising one or more windings; or
a rotor comprising one or more windings configured to be short circuited.

11. The system of claim 9, wherein the controller is configured to filter the induced voltage signal to reduce noise in the induced voltage signal before determining the time constant.

12. The system of claim 9, wherein the controller is configured to determine the time constant based on a regression calculation configured to determine a slope of the decay pattern, wherein the decay pattern is associated with a switching off of an electrical supply configured to couple to the stator, and wherein the slope of the decay pattern correlates to the temperature of the winding based on the time constant.

13. The system of claim 9, wherein the controller is configured to determine an additional temperature of a component thermally coupled to the rotor based on the temperature and a thermal model.

14. The system of claim 9, wherein the controller is configured to adjust the one or more operations of the motor by adjusting an operation of an electrical supply configured to couple to the stator.

15. A method, comprising:
receiving, via a processor, a voltage signal from one or more sensors, wherein the voltage signal comprises a voltage decay of an induced voltage signal associated with a first winding of a stator of a motor, and wherein the voltage decay is associated with a time period that corresponds to when an electrical supply removes a power supply to the stator;
determining, via the processor, a time constant associated with the voltage decay;
determining, via the processor, a temperature of a second winding of a rotor of the motor based at least in part on the time constant; and
adjusting, via the processor, one or more operations of the motor based on the temperature.

16. The method of claim 15, comprising:
generating, via the processor, a visualization comprising the temperature; and
presenting the visualization via a display.

17. The method of claim 15, wherein the temperature of the second winding is determined according to:
$${T}_{t} = {T}_{o} + \frac{1}{α} ( \frac{{τ}_{ro}}{{τ}_{rt}} - 1 )$$
wherein Tₜ is the temperature of the second winding, Tₒ is an additional temperature of the second winding, α is a temperature coefficient of resistivity of the second winding, τᵣₒ is an additional time constant at the additional temperature of the second winding, and τᵣₜ is the time constant.

18. The method of claim 17, comprises receiving, via the processor, from memory, from input to input/output ports, or from any combination thereof, data indicative of the temperature coefficient of resistivity, the additional temperature of the second winding, and the additional time constant.

19. The method of claim 15, wherein determining the time constant comprises:
performing, via the processor, a noise reduction filter to create a filtered induced voltage signal based on the induced voltage signal;
performing, via the processor, a Hilbert transform, to create a Hilbert transformed induced voltage signal magnitude based on the filtered induced voltage signal;
determining, via the processor, a contribution from remanence of a core of the rotor based on the Hilbert transformed induced voltage signal magnitude;
subtracting, via the processor, from the Hilbert transformed induced voltage signal magnitude the contribution from remanence to create an unbiased Hilbert transformed induced voltage signal magnitude; and
performing, via the processor, a log transform on the unbiased Hilbert transformed induced voltage signal magnitude to create a log transform of the induced voltage signal.

20. The method of claim 19, comprises determining, via the processor, the time constant based on a regression calculation, wherein the regression calculation is associated with the log transform.
